(19) United States
(12) Patent Application Publication
(10) Pub. No.: US 2026/0107791 A1
(43) Pub. Date: Apr. 16, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Chia-Chen CHIAO, Taichung City (TW); Chao-Ya YANG, Taichung City (TW); Chien-Cheng LIN, Taichung City (TW)

(21) Appl. No.: 19/057,535

(22) Filed: Feb. 19, 2025

(30) Foreign Application Priority Data
Oct. 11, 2024 (TW) 113138782

(51) Int. Cl. H01L 23/538; H01L 21/48; H01L 21/56; H01L 23/00; H01L 23/31; H01L 25/00; H01L 25/18

(52) U.S. Cl. CPC H10W 70/611; H10W 70/092; H10W 70/65; H10W 74/127; H10W 90/00; H10W 90/401; H10W 74/012; H10W 74/15; H10W 90/724

(57) ABSTRACT

Provided are an electronic package and a manufacturing method thereof. A groove is formed in a carrier structure, and a circuit structure is disposed in the groove. Therefore, chips with different specifications can be used as a first electronic component and a second electronic component electrically connected to the carrier structure and the circuit structure, respectively, thereby multi-functional requirements can be met.

### CROSS-REFERENCE TO RELATED APPLICATIONS

The present application is based upon and claims the right of priority to TW Patent Application No. 113138782, filed Oct. 11, 2024, the disclosure of which is hereby incorporated by reference herein in its entirety for all purposes

### BACKGROUND

### 1. Technical Field

The present disclosure relates to a semiconductor device, and more particularly, to an electronic package and a manufacturing method thereof.

### 2. Description of Related Art

With the vigorous development of the electronics industry, current wireless communication technology has been widely applied in various consumer electronic products to facilitate the reception or transmission of various wireless signals. In order to satisfy the appearance design requirements of consumer electronic products, the manufacturing and design of wireless communication modules are developed toward the requirements of light, thin, short, and small. Patch antennas are widely used in wireless communication modules of electronic products such as cell phones due to their small volume, light weight, and ease of manufacturing

FIG. 1 is a schematic perspective view of a conventional wireless communication module 1. As shown in FIG. 1, the wireless communication module 1 includes: a substrate 10, a plurality of electronic components 11 disposed on the substrate 10, an antenna structure 12, and a packaging material 13. The substrate 10 is a circuit board and is in a rectangular shape. The electronic component 11 is a radio frequency chip and/or a millimeter wave chip, which is disposed on the substrate 10 and electrically connected to the substrate 10. The antenna structure 12 is planar and has an antenna body 120 and a wire 121, and the antenna body 120 is electrically connected to the electronic component 11 through the wire 121. The packaging material 13 encapsulates the electronic component 11 and a part of the wire 121.

If millimeter wave chips for 5G mmWave signals are used as the electronic component 11, a connection of the electronic component 11 to a substrate 10 made of a dielectric layer with low dielectric constant/dielectric loss factor (low DK/Df) is usually required to reduce the signal/energy loss, while other radio frequency chips have no limitations on the dielectric materials for the substrate 10.

On the other hand, if a radio frequency chip is used as the electronic component 11, then it needs to be connected to the substrate 10 with fine circuit specifications to completely wire the electrical contacts of the radio frequency chip to the other side of the substrate 10, but millimeter wave chips do not need to use the substrate 10 with fine circuit specifications.

However, in the conventional wireless communication module 1, when chips (radio frequency chips, millimeter wave chip) with different specifications are used as the electronic component 11, the substrate 10 with different specifications need to be considered, thus it is impossible to arrange the electronic component 11 with different specifications on the existing substrate 10 with a single specification, that is, it is impossible to arrange the radio frequency chips and millimeter wave chips at the same time, and thus the multi-functional requirements cannot be met.

Furthermore, to arrange millimeter wave chips and radio frequency chips for 5G mmWave signals at the same time, it is required to manufacture a special substrate 10 that meets specifications of fine circuits and low DK/Df dielectric layers, thereby manufacturing cost will increase significantly, making it difficult to reduce the overall cost of the end products.

Therefore, how to overcome the aforementioned problems of conventional techniques has become an urgent issue to be solved.

### SUMMARY

In view of the aforementioned shortcomings of the prior art, the present disclosure provides an electronic package including: a carrier structure including a wiring layer and having a first side, a second side opposite to the first side, and at least one groove connecting the first side with the second side; a circuit structure disposed in the groove and having a circuit layer; a first electronic component disposed on the circuit structure corresponding to the first side of the carrier structure and electrically connected to the circuit layer; a second electronic component is disposed on the first side of the carrier structure and electrically connected to the wiring layer; a conductive structure bridges the carrier structure and the circuit structure, and is electrically connected to the wiring layer and the circuit layer; and a packaging layer encapsulates the first electronic component.

The present disclosure further provides a method of manufacturing an electronic package, the method including: providing a carrier structure including a wiring layer and having a first side, a second side opposite to the first side, and at least one groove to connect the first side with the second side; disposing at least a circuit structure having a circuit layer in the groove; disposing a first electronic component on the circuit structure corresponding to the first side of the carrier structure, thereby the first electronic component is electrically connected to the circuit layer; disposing a second electronic component on the first side of the carrier structure, thereby the second electronic component is electrically connected to the wiring layer; bridging the carrier structure and the circuit structure through a conductive structure, thereby the conductive structure is electrically connected to the wiring layer and the circuit layer; and encapsulating the first electronic component through a packaging layer.

In the aforementioned electronic package and a manufacturing method thereof, the packaging layer extends into the groove to cover the circuit structure.

In the aforementioned electronic package and a manufacturing method thereof, the packaging layer further covers the conductive structure.

In the aforementioned electronic package and a manufacturing method thereof, a plurality of the grooves are formed on the carrier structure, each of the grooves is disposed with the circuit structure, and thus the first side of the carrier structure are configured with a plurality of the first electronic components and a plurality of the conductive structures. For example, a plurality of the packaging layers are formed on the first side of the carrier structure to correspondingly encapsulate each of the first electronic components. Alternatively, the packaging layer encapsulates a plurality of the first electronic components.

In the aforementioned electronic package and a manufacturing method thereof, the packaging layer further encapsulates the second electronic component.

In the aforementioned electronic package and a manufacturing method thereof, the packaging layer further extends to a side of the carrier structure.

In the aforementioned electronic package and a manufacturing method thereof, the conductive structure is disposed on the first side or the second side of the carrier structure.

In the aforementioned electronic package and a manufacturing method thereof, the conductive structure is an interposer, a bonding wire, an active element, a passive element, or a combination thereof.

As can be seen from the above, the electronic package and a manufacturing method thereof of the present disclosure mainly dispose the circuit structure in the groove of the carrier structure to form substrate areas with different specifications. Therefore, compared with the conventional technology, in the electronic package of the present disclosure, the first electronic component and the second electronic component can be disposed on the required substrate areas according to their specifications. As such, when chips with different specifications are used in the electronic package, chips with different specifications can be used as the first electronic component and the second electronic component to be configured on the circuit structure and the carrier structure at the same time, thereby the multi-functional requirements can be met.

Besides, the circuit structure and the carrier structure can be manufactured by the existing technologies and equipment, and there is no need to add new processes and new materials or purchase new special machines. Compared with the conventional technology, there is no additional cost generated for the electronic package of the present disclosure during the manufacturing, which facilitates to reduce the manufacturing cost of the electronic package, thereby effectively reducing the overall cost of the end products.

### BRIEF DESCRIPTION OF THE DRAWINGS

FIG. 1 is a schematic prospective view showing a conventional wireless communication module.

FIG. 2A to FIG. 2D are schematic cross-sectional view showing the manufacturing method of an electronic package of the present disclosure.

FIG. 2E is a schematic top view of FIG. 2D.

FIG. 3A, FIG. 4A, FIG. 5A, FIG. 6A, FIG. 7A, FIG. 8A, and FIG. 9A are schematic cross-sectional views showing various aspects of an electronic package of the present disclosure.

FIG. 3B, FIG. 4B, FIG. 5B, FIG. 6B, FIG. 7B, FIG. 8B, and FIG. 9B are schematic top views of FIG. 3A, FIG. 4A, FIG. 5A, FIG. 6A, FIG. 7A, FIG. 8A, and FIG. 9A, respectively.

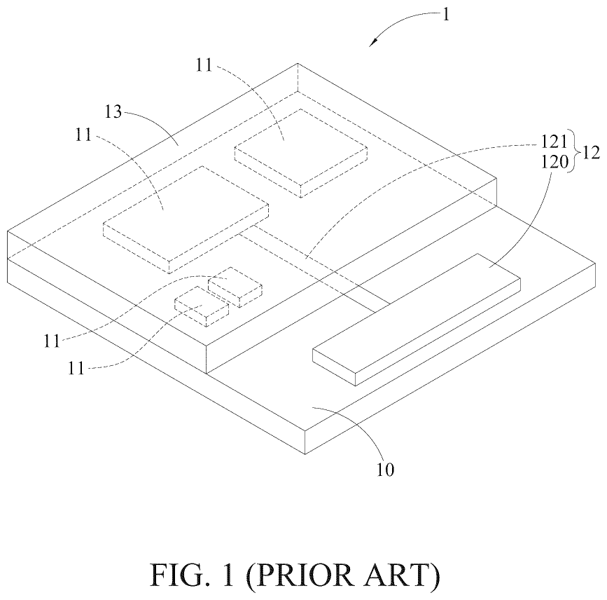

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” and “a” and the like are merely for clear explanation rather than limiting the practicable scope of the present disclosure, and thus, alterations or adjustments of the relative relationships thereof without essentially altering the technical contents should still be considered in the practicable scope of the present disclosure.

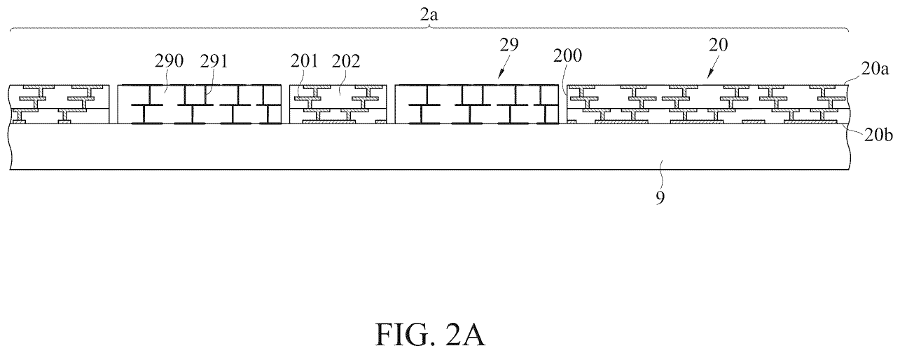

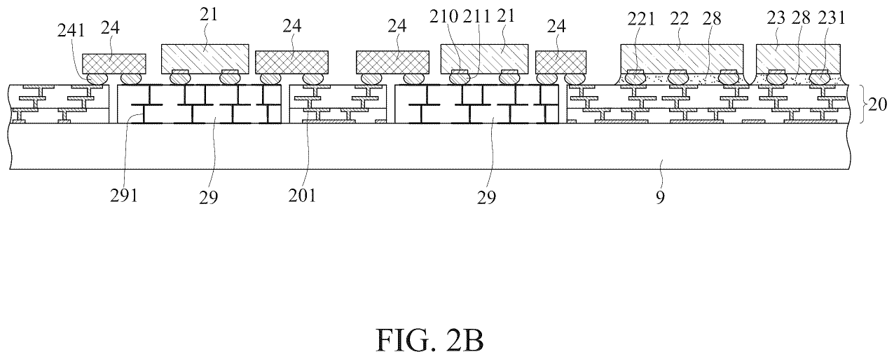

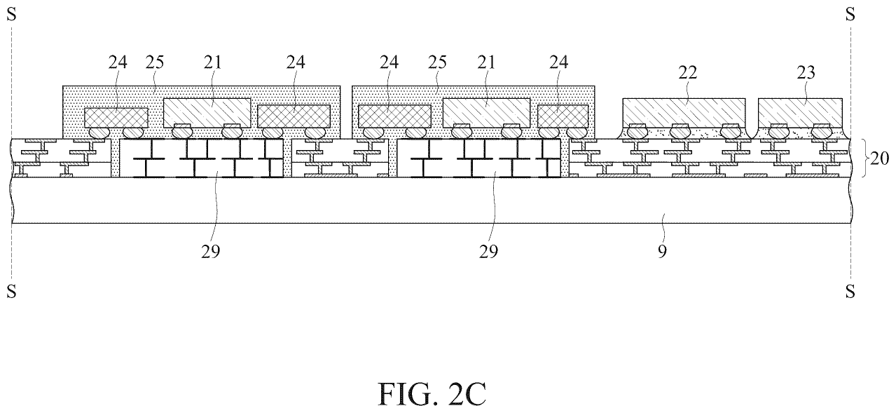

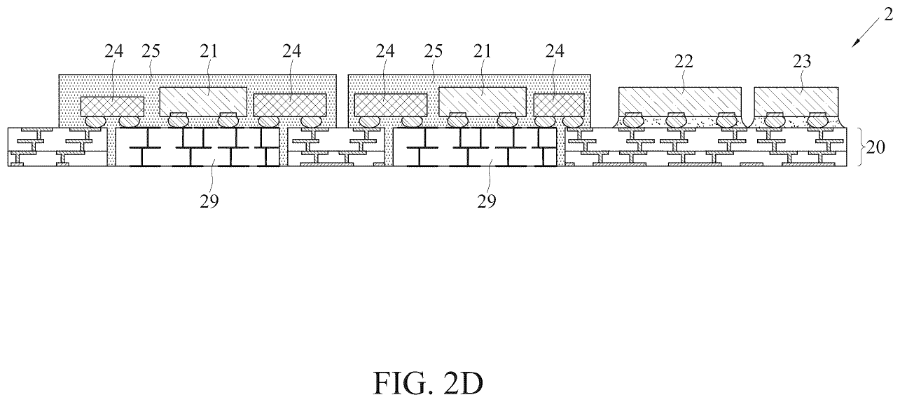

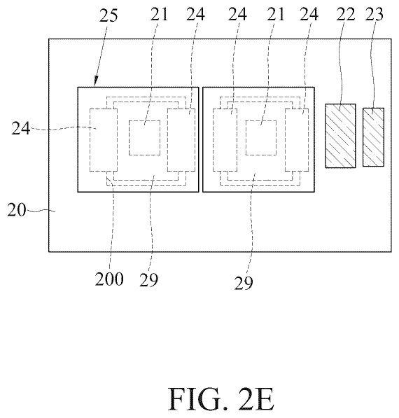

FIG. 2A to FIG. 2D are schematic cross-sectional view showing the manufacturing method of an electronic package 2 of the present disclosure.

As shown in FIG. 2A, a carrier structure 20 is disposed on a carrier 9, the carrier structure 20 is defined with a first side 20a and a second side 20b opposite to the first side 20a, and the carrier structure 20 has at least one groove 200 connecting the first side 20a and the second side 20b, so as to place at least one circuit structure 29 in the groove 200, thereby the carrier structure 20 and the circuit structure 29 are served as a substrate module 2a.

In one embodiment, the carrier structure 20 is, for example, a packaging substrate with a core layer, a coreless packaging substrate, or other wiring structure, which is combined with at least one wiring layer 201, such as redistribution layer (RDL) specification, on an insulating material 202. For example, the insulating material 202 can be a dielectric material such as polybenzoxazole (PBO), polyimide (PI), prepreg (PP), or others.

Besides, the circuit structure 29 includes at least one insulating layer 290 and a circuit layer 291, such as the redistribution layer (RDL) specification, combined with the insulating layer 290. For example, the insulating layer 290 can be a dielectric material such as polybenzoxazole (PBO), polyimide (PI), prepreg (PP), or others.

It should be understood that the carrier structure 20 can also be other base materials for carrying chips, such as a board with metal routing, but not limited to the above.

As shown in FIG. 2B, at least one (such as two) first electronic component 21 is disposed on the circuit structure 29 corresponding to the first side 20a, at least one second electronic component 22 and at least one third electronic component 23 are disposed on the first side 20a of the carrier structure 20, and at least one (such as four) conductive structure 24 is disposed to bridge the circuit structure 29 and the first side 20a of the carrier structure 20.

In one embodiment, the first electronic component 21 is an active element, a passive element, or a combination thereof. The active element can be, for example, a semiconductor chip, and the passive element can be, for example, a resistor, a capacitor, and an inductor. For example, the first electronic component 21 is a semiconductor chip such as a radio frequency chip or a millimeter wave chip, which has a plurality of electrode pads 210 and is electrically connected to the circuit layer 291 through a plurality of conductive bumps 211 in a flip-chip manner.

In addition, the second electronic component 22 and the third electronic component 23 are active elements, passive elements, or combinations thereof. The active element can be, for example, a semiconductor chip, and the passive element can be, for example, a resistor, a capacitor, and an inductor. For example, the second electronic component 22 and the third electronic component 23 can be semiconductor chips such as radio frequency chips or millimeter wave chips, which are electrically connected to the wiring layer 201 through a plurality of conductive bumps 221, 231 in a flip-chip manner, and the plurality of conductive bumps 221, 231 are encapsulated by an underfill 28.

Furthermore, the conductive structure 24 is an interposer, which is electrically connected to the wiring layer 201 and the circuit layer 291 through a plurality of conductive bumps 241. The material of the interposer can be a Through Silicon Interposer (TSI) or an organic circuit board.

It should be understood that regarding electrical connections of the first electronic component 21, the second electronic component 22, the third electronic component 23, and even the conductive structure 24 to the substrate module 2a can be various such as wire bonding, and is not limited to the above.

As shown in FIG. 2C, a plurality of packaging layers 25 are formed on the carrier structure 20 and the circuit structure 29, such that each of the packaging layers 25 encapsulates each of the first electronic components 21 and the conductive structures 24 next to the first electronic components 21, and is filled in the groove 200 to cover the circuit structure 29.

In one embodiment, the packaging layer 25 is an insulating material, such as polyimide (PI), dry film, molding colloid or molding compound such as epoxy resin. For example, the manufacturing process of the packaging layer 25 can be formed by liquid compound, injection, lamination, or compression molding.

As shown in FIG. 2D and FIG. 2E, the carrier 9 is removed, and a singulation process is performed along a cutting path S as shown in FIG. 2C to obtain the required electronic package 2.

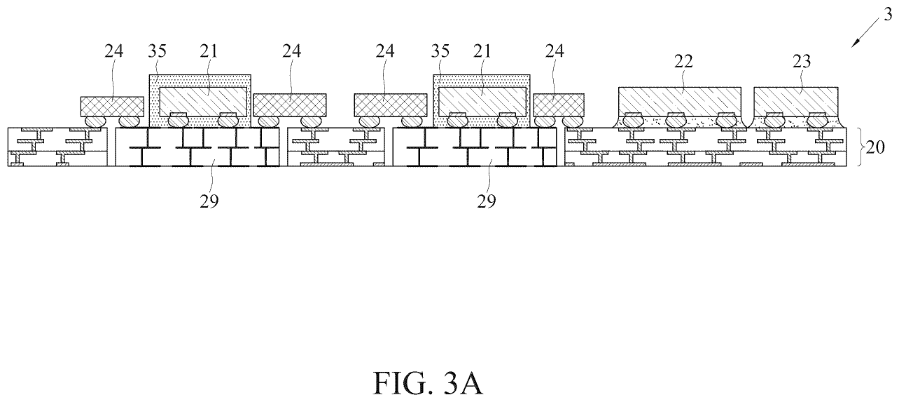

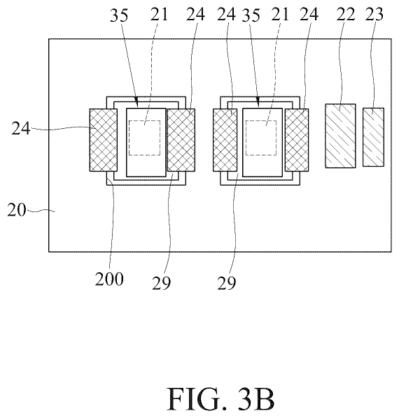

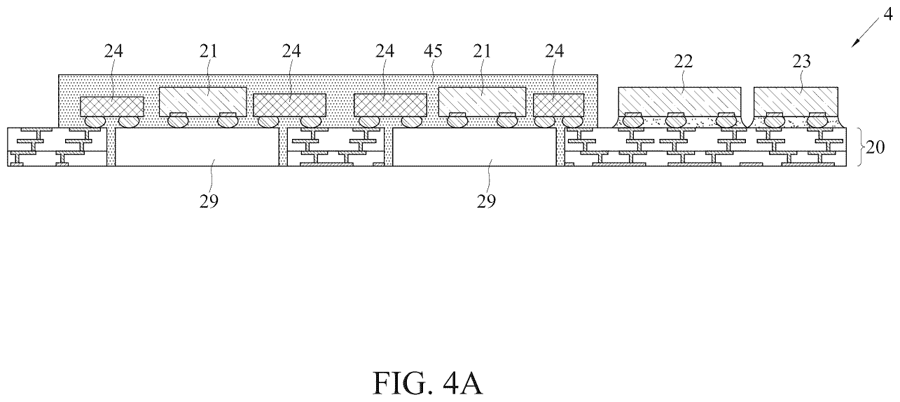

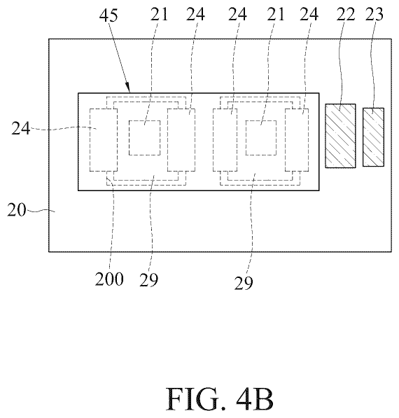

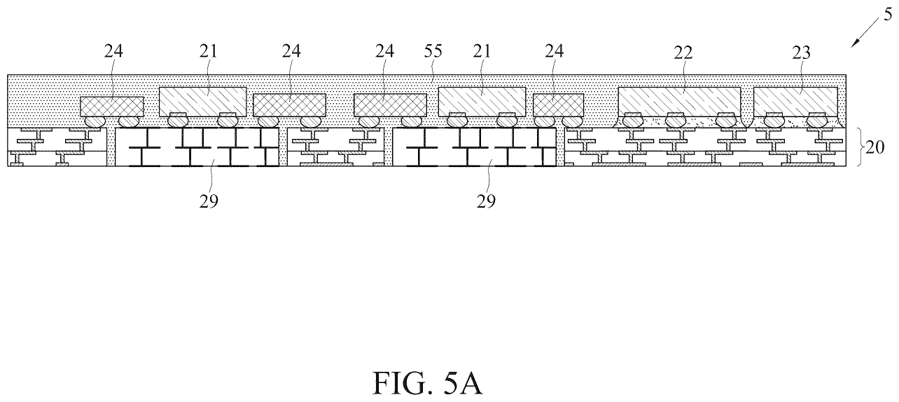

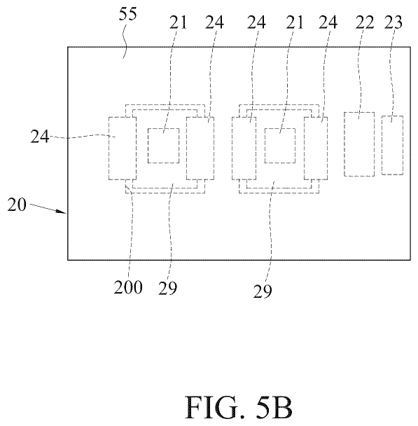

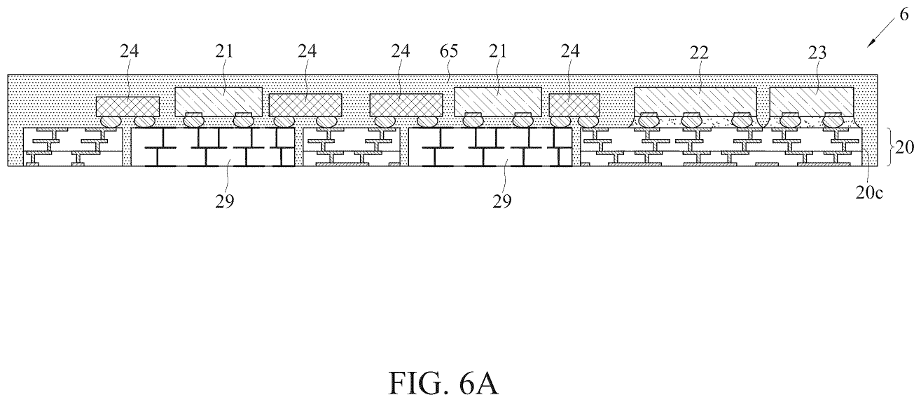

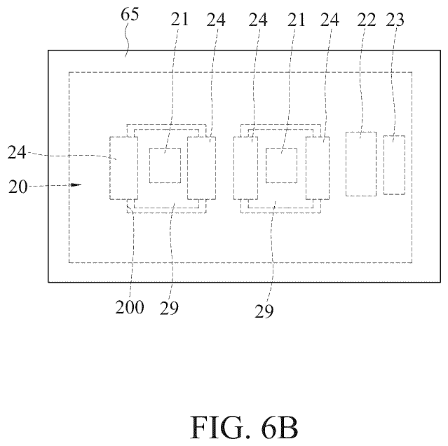

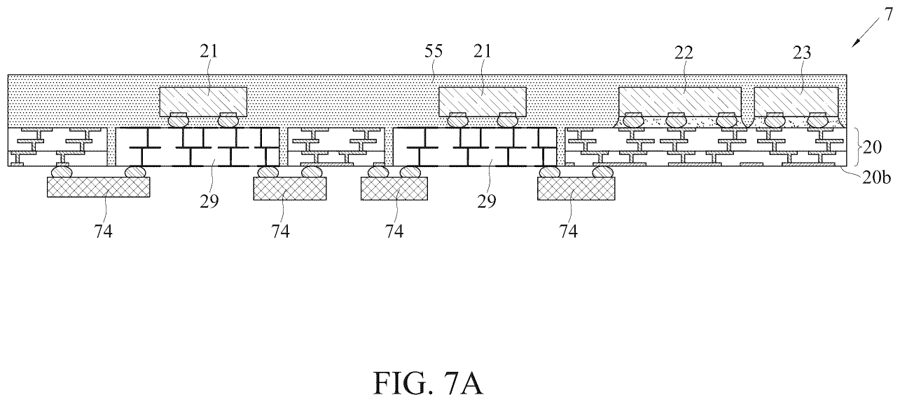

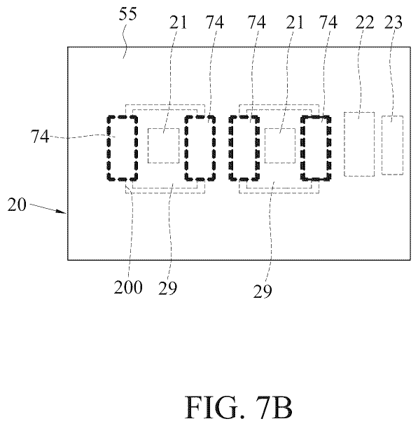

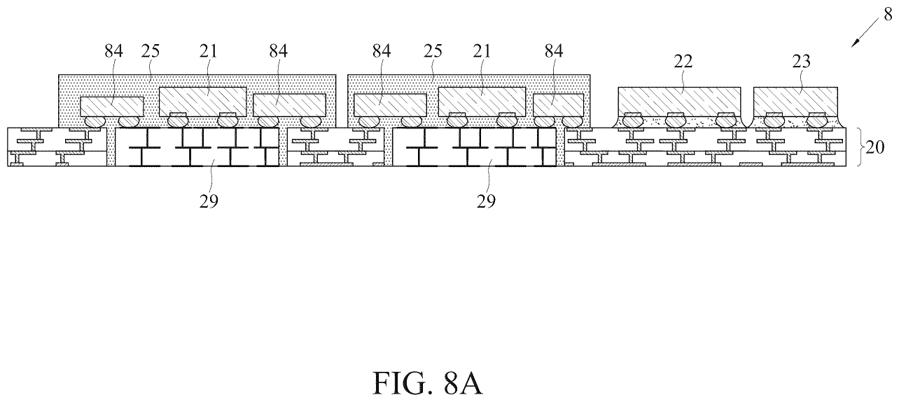

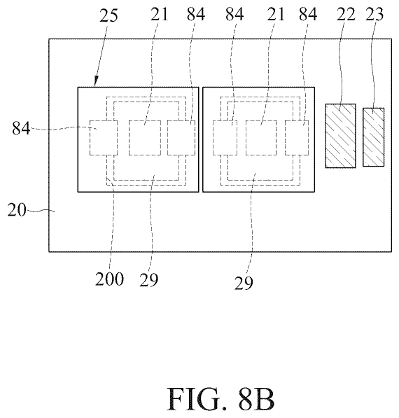

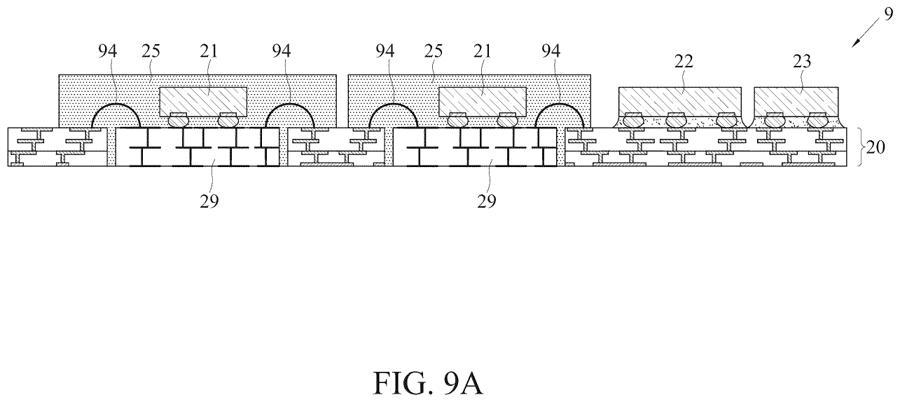

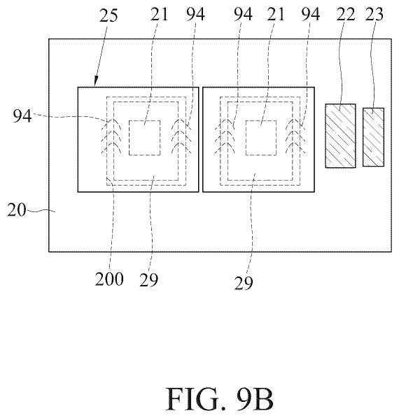

In another embodiment, as an electronic package 3 shown in FIG. 3A and FIG. 3B, a packaging layer 35 can only encapsulate the first electronic component 21 rather than cover the conductive structure 24 and the circuit structure 29.

In other embodiments, as an electronic package 4 shown in FIG. 4A and FIG. 4B, the electronic package 4 can also encapsulate all the first electronic components 21, all the conductive structures 24, and the circuit structure 29 by a single packaging layer 45.

Additionally, as an electronic package 5 shown in FIG. 5A and FIG. 5B, the packaging layer 55 can encapsulate the first electronic component 21, the second electronic component 22, the third electronic component 23, and the conductive structure 24 disposed on the carrier structure 20 and the circuit structure 29.

Further, as an electronic package 6 shown in FIG. 6A and FIG. 6B, in addition to being formed on the carrier structure 20 and the circuit structure 29, a packaging layer 65 can also extend to a side 20c of the carrier structure 20 to cover the carrier structure 20.

Besides, as an electronic package 7 shown in FIG. 7A and FIG. 7B, a conductive structure 74 can be disposed on the second side 20b of the carrier structure 20 according to requirements, such that the conductive structure 74 is located on a different side from the first electronic component 21, the second electronic component 22, and the third electronic component 23.

Alternatively, as an electronic package 8 shown in FIG. 8A and FIG. 8B, a conductive structure 84 can be a bridge die constituted by active elements, passive elements, or combinations thereof as structures of the first electronic component 21, the second electronic component 22, and the third electronic component 23.

As a carrier 9 shown in FIG. 9A and FIG. 9B, even a conductive structure 94 can be a bonding wire for wire bonding.

It should be understood that there are various structure types and configuration ways of the conductive structures 24, 74, 84, 94, which mainly provide electrical connection between the wiring layer 201 and the circuit layer 291.

Hence, in the manufacturing process of the electronic package of the present disclosure, the circuit structure 29 is mainly placed in the groove 200 of the carrier structure 20, and thus the substrate areas with different specifications according to requirements can be designed on the substrate module 2a. For example, the circuit layer 291 of the circuit structure 29 meets the requirements of fine circuits, and the insulating material 202 of the carrier structure 20 meets the requirements of low DK/Df dielectric layer specifications (or, the wiring layer 201 of the carrier structure 20 meets the requirements of fine circuit, and the insulating layer 290 of the circuit structure 29 meets the requirements of low DK/Df dielectric layer specifications). Therefore, compared with the conventional technology, the first electronic component 21 (the radio frequency chip or the millimeter wave chip) and the second electronic component 22 (the radio frequency chip or the millimeter wave chip) can be disposed on the required substrate areas according to their specifications in the electronic packages 2-9 of the present disclosure. When chips (such as the radio frequency chip or the millimeter wave chip) with different specifications are required for the electronic packages 2-9, the radio frequency chip or the millimeter wave chip can be arranged on the circuit structure 29 and the carrier structure 20 at the same time, thereby the multi-functional requirements can be meet.

Besides, the substrate module 2a can be manufactured by adopting the existing technologies and equipment, there is no need to add new processes and new materials or purchase new special machines, thus there is no additional cost generated by the manufacturing method of the present disclosure, which facilitates to reduce the manufacturing cost of the electronic packages 2-9, thereby the overall cost of the end products can be effectively reduced.

The present disclosure also provides the electronic package 2-9 including: the carrier structure 20 with the wiring layer 201, at least one circuit structure 29, at least one first electronic component 21, at least one second electronic component 22, at least one conductive structure 24, 74, 84, 94, and at least one packaging layer 25, 35, 45, 55, 65.

The carrier structure 20 is defined with the first side 20a and the second side 20b opposite to the first side 20a, and at least one groove 200 is formed to connect the first side 20a and the second side 20b.

The circuit structure 29 is disposed in the groove 200 and has the circuit layer 291.

The first electronic component 21 is disposed on the circuit structure 29 corresponding to the first side 20a and electrically connected to the circuit layer 291.

The second electronic component 22 is disposed on the first side 20a of the carrier structure 20 and electrically connected to the wiring layer 201.

The conductive structure 24, 74, 84, 94 bridges the carrier structure 20 and the circuit structure 29, and electrically connected to the wiring layer 201 and the circuit layer 291.

The packaging layer 25, 35, 45, 55, 65 encapsulates the first electronic component 21.

In one embodiment, the packaging layer 25, 45, 55, 65 extends into the groove 200 to cover the circuit structure 29.

In one embodiment, the packaging layer 25, 45, 55, 65 further covers the conductive structure 24, 84, 94.

In one embodiment, a plurality of the grooves 200 are formed on the carrier structure 20 to dispose the circuit structure 29 in each of the grooves 200 respectively, and thus a plurality of the first electronic components 21 and a plurality of the conductive structures 24, 84, 94 are disposed on the first side 20a of the carrier structure 20. For example, a plurality of the packaging layers 25, 35 are formed on the first side 20a of the carrier structure 20 to correspondingly encapsulate each of the first electronic components 21 respectively. Alternatively, the packaging layer 45, 55, 65 encapsulates the plurality of the first electronic components 21.

In one embodiment, the packaging layer 55, 65 further encapsulates the second electronic component 22.

In one embodiment, the packaging layer 65 further extends to the side 20c of the carrier structure 20.

In one embodiment, the conductive structure 24, 74 is disposed on the first side 20a or the second side 20b of the carrier structure 20.

In one embodiment, the conductive structure 24, 74, 84, 94 is an interposer, a bonding wire, an active element, a passive element, or a combination thereof.

To sum up, the electronic package and a manufacturing method thereof of the present disclosure have the circuit structure dispose the circuit structure in the groove of the carrier structure to form substrate areas with different specifications. Therefore, in the electronic package of the present disclosure, the first electronic component and the second electronic component can be disposed on the required substrate areas according to their specifications. As such, when electronic components (chips) with different specifications are used in the electronic package, the electronic components with different specifications can be configured on the circuit structure and the carrier structure at the same time, thereby the multi-functional requirements can be met.

Besides, the circuit structure and the carrier structure can be manufactured by the existing technologies and equipment, and there is no need to add new processes and new materials or purchase new special machines. Accordingly, there is no additional cost generated for the electronic package of the present disclosure during the manufacturing, which facilitates to reduce the manufacturing cost of the electronic package, thereby effectively reducing the overall cost of the end products.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package comprising:
a carrier structure including a wiring layer and having a first side, a second side opposite to the first side, and at least one groove connecting the first side with the second side;
a circuit structure disposed in the groove and having a circuit layer;
a first electronic component disposed on the circuit structure corresponding to the first side of the carrier structure and electrically connected to the circuit layer;
a second electronic component disposed on the first side of the carrier structure and electrically connected to the wiring layer;
a conductive structure bridging the carrier structure and the circuit structure and electrically connected to the wiring layer and the circuit layer; and
a packaging layer encapsulating the first electronic component.

2. The electronic package of claim 1, wherein the packaging layer extends into the groove to cover the circuit structure.

3. The electronic package of claim 1, wherein the packaging layer further covers the conductive structure.

4. The electronic package of claim 1, wherein a plurality of the grooves are formed on the carrier structure, and each of the grooves is formed with the circuit structure thereon, such that the first side of the carrier structure has a plurality of the first electronic components and a plurality of the conductive structures.

5. The electronic package of claim 4, wherein a plurality of the packaging layers are formed on the first side of the carrier structure to correspondingly encapsulate each of the first electronic components.

6. The electronic package of claim 4, wherein the packaging layer encapsulates the plurality of the first electronic components.

7. The electronic package of claim 1, wherein the packaging layer further encapsulates the second electronic component.

8. The electronic package of claim 1, wherein the packaging layer further extends to a side of the carrier structure.

9. The electronic package of claim 1, wherein the conductive structure is disposed on the first side or the second side of the carrier structure.

10. The electronic package of claim 1, wherein the conductive structure is an interposer, a bonding wire, an active element, a passive element, or a combination thereof.

11. A method of manufacturing an electronic package, the method comprising:
providing a carrier structure including a wiring layer and having a first side, a second side opposite to the first side, and at least one groove to connect the first side with the second side;
disposing at least a circuit structure having a circuit layer in the groove;
disposing a first electronic component on the circuit structure corresponding to the first side of the carrier structure, and electrically connecting the first electronic component to the circuit layer;
disposing a second electronic component on the first side of the carrier structure, and electrically connecting the second electronic component to the wiring layer;
bridging the carrier structure and the circuit structure through a conductive structure, in a manner that the conductive structure is electrically connected to the wiring layer and the circuit layer; and
encapsulating the first electronic component through a packaging layer.

12. The method of claim 11, wherein the packaging layer extends into the groove to cover the circuit structure.

13. The method of claim 11, wherein the packaging layer further covers the conductive structure.

14. The method of claim 11, wherein a plurality of the grooves are formed on the carrier structure, each of the grooves is disposed with the circuit structure, and thus the first side of the carrier structure are configured with a plurality of the first electronic components and a plurality of the conductive structures.

15. The method of claim 14, wherein a plurality of the packaging layers are formed on the first side of the carrier structure to correspondingly encapsulate each of the first electronic components.

16. The method of claim 14, wherein the packaging layer encapsulates a plurality of the first electronic components.

17. The method of claim 11, wherein the packaging layer further encapsulates the second electronic component.

18. The method of claim 11, wherein the packaging layer further extends to a side of the carrier structure.

19. The method of claim 11, wherein the conductive structure is disposed on the first side or the second side of the carrier structure.

20. The method of claim 11, wherein the conductive structure is an interposer, a bonding wire, an active element, a passive element, or a combination thereof.
